(19) United States
(12) Patent Application Publication
(10) Pub. No.: US 2023/0198486 A1
(43) Pub. Date: Jun. 22, 2023

(54) ADAPTIVE MUSIC SELECTION USING MACHINE LEARNING OF NOISE FEATURES, MUSIC FEATURES AND CORRELATED USER ACTIONS

(71) Applicant: Telefonaktiebolaget LM Ericsson (publ), Stockholm (SE)

(72) Inventors: Peter Ökvist, LULEÅ (SE); Tommy Arngren, SÖDRA SUNDERBYN (SE)

(21) Appl. No.: 17/918,319

(22) PCT Filed: Apr. 16, 2020
(86) PCT No.: PCT/EP2020/060722

§ 371 Date: Oct. 11, 2022

(51) Int. Cl. H03G 3/32; H03G 5/16; G06F 3/16

(52) U.S. Cl. CPC H03G 3/32; H03G 5/165; G06F 3/165

(57) ABSTRACT

An adaptive music system includes at least one processing circuit operative to characterize ambient noise features of digitized ambient noise obtained from a microphone circuit associated with a user device and characterizes music features of digitized music being played through the user device to a speaker. The at least one processing circuit is further operative to generate a music playout command responsive to processing the characterized ambient noise features and the characterized music features through a machine learning model that has been trained based on a combination of historical user actions to control music playout, historically characterized ambient noise features that are correlated in time to the historical user actions, and historically characterized music features that are correlated in time to the historical user actions. The at least one processing circuit is further operative to control music playout through the user device responsive to the music playout command.

### TECHNICAL FIELD

The present disclosure relates to an adaptive music system, a method by an adaptive music system, and a corresponding computer program product.

### BACKGROUND

Music streaming has become a common application of user devices. Streaming music can be played through a myriad of different user devices, which include smartphones, tablet computers, desktop computers, MP3 music players, digital media players (e.g., Apple TV, Roku, media streaming application run on smart TV, etc.), headphones (in-ear, on-ear, over-ear), WIFI speakers, home agents, vehicle-based audio systems, etc. These user devices may be configured to receive the digitized music directly from streaming servers or indirectly via a media streaming capability of another user device.

Microphones have become commonplace in user devices. For example, some headphones include microphones used for ambient noise cancellation, to change music loudness based on ambient noise, or to amplify the user's ability to listen to ambient sounds. Some user devices use the microphones to mute music playout when the user's voice is detected or when the noise of an approaching car is sensed.

### SUMMARY

Some embodiments disclosed herein are directed to an adaptive music system. The adaptive music system includes at least one processing circuit operative to characterize ambient noise features of digitized ambient noise obtained from a microphone circuit associated with a user device and to characterize music features of digitized music being played through the user device to a speaker. The at least one processing circuit is further operative to generate a music playout command responsive to processing the characterized ambient noise features and the characterized music features through a machine learning model that has been trained based on a combination of historical user actions to control music playout, historically characterized ambient noise features that are correlated in time to the historical user actions, and historically characterized music features that are correlated in time to the historical user actions. The at least one processing circuit is operative to control music playout through the user device responsive to the music playout command

Potential advantages of these operations are that the music playout is controlled using a machine learning model that correlates historical user actions to control music playout with historically characterized ambient noise features and historically characterized music features. In this manner, the user's preferences for how music playout is controlled are learned for a myriad of combinations of ambient noise and music characteristics, and the trained machine learning model is then used to control music playout in ways that should satisfy that particular user's preferences. Moreover, the machine learning model can be adapted based on crowd-sourced input indicating those users' music playout control preferences when subjected to certain combinations of ambient noise and music characteristics, which can enable the adaptive music system to more accurately adapt to the regional and/or demographic similar preferences of users.

Some other related embodiments are directed to a method by an adaptive music system. The method includes characterizing ambient noise features of digitized ambient noise obtained from a microphone circuit associated with a user device and characterizing music features of digitized music being played through the user device to a speaker. The method further includes generating a music playout command responsive to processing the characterized ambient noise features and the characterized music features through a machine learning model that has been trained based on a combination of historical user actions to control music playout, historically characterized ambient noise features that are correlated in time to the historical user actions, and historically characterized music features that are correlated in time to the historical user actions. The method further includes controlling music playout through the user device responsive to the music playout command

Other related systems, methods, and computer program products according to embodiments will be or become apparent to one with skill in the art upon review of the following drawings and detailed description. It is intended that all such additional systems, methods, and computer program products be included within this description and protected by the accompanying claims.

### BRIEF DESCRIPTION OF THE DRAWINGS

Aspects of the present disclosure are illustrated by way of example and are not limited by the accompanying drawings. In the drawings:

FIG. 1 illustrates an adaptive music system that controls music playout through a user device in accordance with some embodiments;

FIG. 2 illustrates component circuits of the adaptive music system of FIG. 1 in accordance with some embodiments;

FIG. 3 illustrates a neural network circuit included in the machine learning model of FIG. 2 in accordance with some embodiments;

FIGS. 4 and 5 are flowcharts of operations performed by the adaptive music system of FIG. 1 in accordance with some embodiments;

FIG. 6 is a block diagram of component circuits of an adaptive music system which are configured to operate in accordance with some embodiments of the present disclosure; and

FIG. 7 is a block diagram of component circuits of a user device which can include functionality of the adaptive music system or can be communicatively connected to the adaptive music system, in accordance with some embodiments of the present disclosure.

### DETAILED DESCRIPTION

Inventive concepts will now be described more fully hereinafter with reference to the accompanying drawings, in which examples of embodiments of inventive concepts are shown. Inventive concepts may, however, be embodied in many different forms and should not be construed as limited to the embodiments set forth herein. Rather, these embodiments are provided so that this disclosure will be thorough and complete, and will fully convey the scope of various present inventive concepts to those skilled in the art. It should also be noted that these embodiments are not mutually exclusive. Components from one embodiment may be tacitly assumed to be present/used in another embodiment.

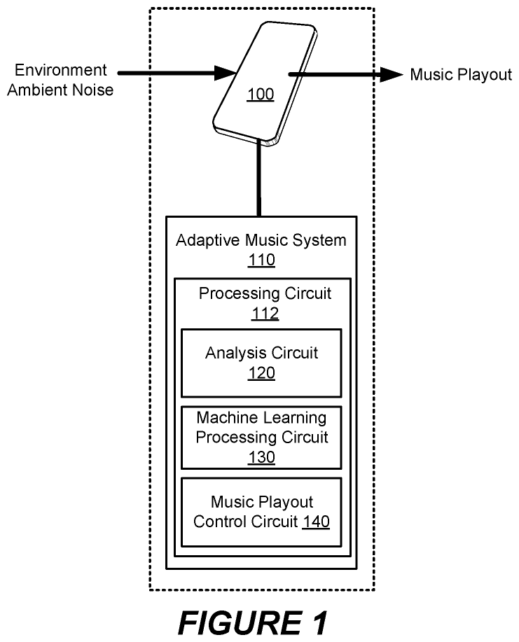

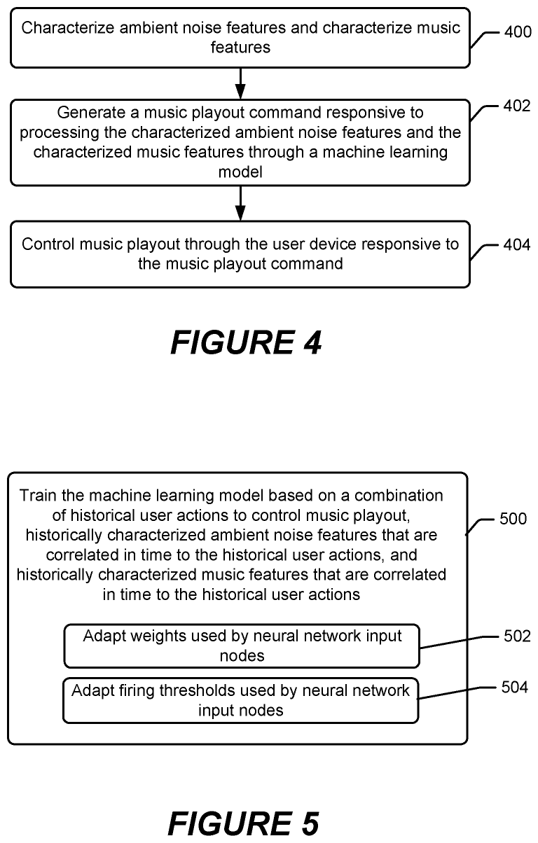

FIG. 1 illustrates an adaptive music system 110 that controls music playout through a user device in accordance with some embodiments. Referring to FIG. 1, the adaptive music system includes at least one processing circuit 112. To facilitate explanation of various functional operations of the processing circuit 112, in the embodiment of FIG. 1 the processing circuit 112 is illustrated as including an analysis circuit 120, a machine learning processing circuit 130, and a music playout control circuit 140. The processing circuit 112 may have more or less circuits than are shown in FIG. 1. For example, as explained further below, any one or more of the analysis circuit 120, the machine learning processing circuit 130, and the music playout control circuit 140 may be combined into an integrated circuit or divided into two or more separate circuits. FIGS. 4 and 5 are flowcharts of operations performed by the adaptive music system 110 of FIG. 1 in accordance with some embodiments.

Referring to FIGS. 1 and 4, the analysis circuit 120 is configured to operate 400 to characterize ambient noise features of digitized ambient noise obtained from a microphone circuit associated with a user device 100 and to characterize music features of digitized music being played through the user device 100 to a speaker. The machine learning processing circuit 130 is configured to operate 402 to generate a music playout command responsive to processing the characterized ambient noise features and the characterized music features through a machine learning model that has been trained based on a combination of historical user actions to control music playout, historically characterized ambient noise features that are correlated in time to the historical user actions, and historically characterized music features that are correlated in time to the historical user actions. The music playout circuit 140 is configured to operate 404 to control music playout through the user device responsive to the music playout command.

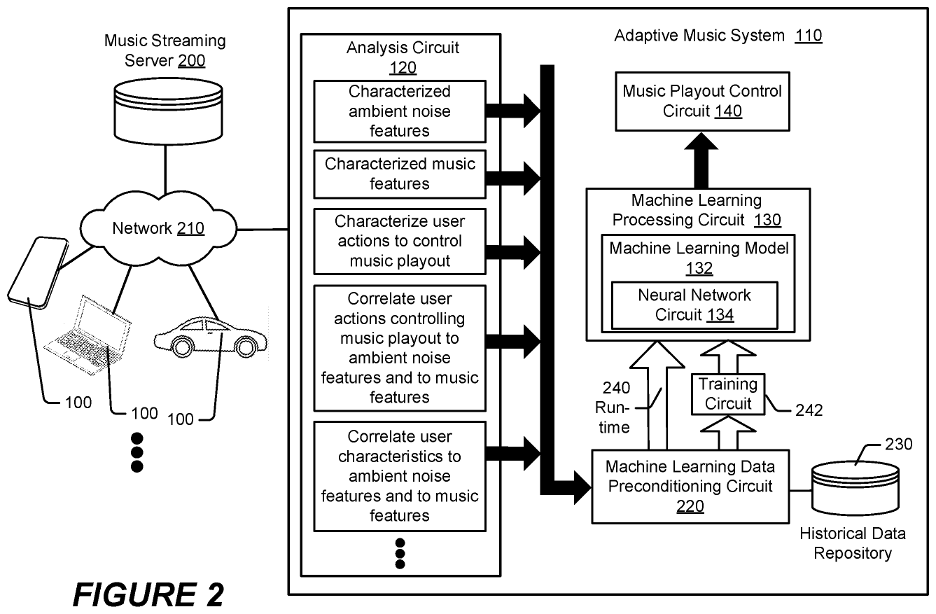

Although the analysis circuit 120, the machine learning processing circuit 130, and music playout control circuit 140 of the adaptive music system 110 are illustrated as being separate from the user device 100 for ease of illustration and explanation only, some or all of these component circuits may reside within the user device 100 or may reside in a network server (e.g., a music streaming server (200 in FIG. 2) such as Spotify, Deezer, Apple Music, etc.) that is communicatively connected to the user device 100. When one or more of the circuit components of the adaptive music system 110 are implemented in a network server, such as a music streaming server, the user device 100 can run an application that operates as a client process that operationally communicates with a host process run on the network server.

Although the analysis circuit 120, the machine learning processing circuit 130, and music playout control circuit 140 are illustrated as separate blocks in FIG. 1 and various other figures herein for ease of illustration and explanation only, any two or more of these circuits may be implemented in a shared circuit, and any of these circuits may be implemented at least partially in digital circuitry, such as by program code stored in at least one memory circuit which is executed by at least one processor circuit comprised in the processing circuit 112.

Potential advantages of these operations are that the music playout is controlled using a machine learning model that correlates historical user actions to control music playout with historically characterized ambient noise features and historically characterized music features. In this manner, the user's preferences for how music playout is controlled are learned for a myriad of combinations of ambient noise and music characteristics, and the trained machine learning model is then used to control music playout in ways that should satisfy that particular user's preferences. Moreover, the machine learning model can be adapted based on crowd-sourced input indicating those users' music playout control preferences when subjected to certain combinations of ambient noise and music characteristics, which can enable the adaptive music system to more accurately adapt to the regional and/or demographic similar preferences of users.

The user device 100 is configured to play digitized music, such as MP3 music or music compressed using any other audio-compression format, that may reside in a music file stored in local memory of the user device 100 or which may be received in a digitized music stream from a music streaming server (200 in FIG. 2). The user device 100 may output the music to a speaker that is part of the user device 100 or which may be connected thereto through a wired or wireless connection. Example types of the user device 100 include, without limitation, a smartphone, tablet computer, desktop computer, music player, digital media player (e.g., Apple TV, Roku, media streaming application hosted by smart TV, etc.), headphones (in-ear, on-ear, over-ear), WIFI speakers, home agent, vehicle-based audio system, etc. The user device 100 can be configured to receive a microphone signal which may be provided by a microphone circuit within the user device 100 or which is connected thereto through a wired or wireless connection. For example, a headset may include a microphone that is configured to provide a digitized microphone signal to the user device 100.

Further operations that may be performed by the adaptive music system 110 of FIG. 1 are now explained with reference to FIG. 2. FIG. 2 illustrates component circuits of the adaptive music system 110 which are configured in accordance with some embodiments. Again, although the adaptive music system 110 is illustrated as being separate from and communicatively connected through a network 210 to various illustrated types of user devices 100 and the music streaming server 200, some or all of the circuit components (e.g., analysis circuit 120, the music playout control circuit 140, the machine learning processing circuit 130, the training circuit 242, etc.) of the adaptive music system 110 may be implemented by circuitry implemented in any one or more of the user devices 100 and/or in the music streaming server 200.

As explained above, the analysis circuit 120 is configured to characterize ambient noise features of digitized ambient noise obtained from a microphone circuit associated with a user device 100 and to characterize music features of digitized music being played through the user device 100 to a speaker.

The characterization of the ambient noise features can include characterizing at least one of ambient noise frequency spectrum (such as the zero-crossing rate, spectral centroid, spectral roll-off, overall shape of a spectral envelope, chroma frequencies, etc.), ambient noise acoustic fingerprint (based on a time-frequency graph of the ambient noise, which may also be called a spectrogram), ambient noise loudness, and ambient noise repetitive pattern. The characterization of the music features of the digitized music being played through the user device 100 to a speaker can include characterizing at least one of music frequency spectrum (such as the zero-crossing rate, spectral centroid, spectral roll-off, overall shape of a spectral envelope, chroma frequencies, etc.), music acoustic fingerprint (based on a time-frequency graph of the music, which may also be called a spectrogram), music loudness, music repetitive pattern, music play time, music popularity, music genre, and music artist.

The zero-crossing rate can correspond to the rate of sign-changes along a signal, i.e., the rate at which the signal changes from positive to negative or back. The spectral envelope can correspond to where the “center-of-mass” for a sound is located, and can be calculated as the weighted mean of the frequencies present in the sound. The spectral roll-off can correspond to a shape-measure of the signal, e.g. representing frequency below which a specified percentage of the total spectral energy is located lies. The overall shape can correspond to the Mel frequency cepstral coefficients (MFCCs) of a signal which are a small set of features (usually about 10-20) which concisely describe the overall shape of a spectral envelope. The chroma frequencies can correspond to a representation of sound in which the entire spectrum is divided into a defined number, e.g., 12, bins representing the defined number, e.g., 12, distinct semitones (or chroma) of the musical octave.

The characterization of the music features can be performed on selected segments of a music track, i.e. dividing the music duration into e.g. N equal parts, and by applying the music feature characterization to its individual segments. In that aspect, individual parts of a music track may be compared to others; e.g. an entry section could be found comprising mostly low-frequency components, whereas a later part of same music track may comprise mostly (high-) midrange components as a result of a guitar crescendo; or vice versa. From this it is understood that parts of a single music track may comprise different sound features, one music track compared another music track may typically carry different sound features, and by that be distinguishable.

The analysis circuit 120 may also characterize the user, the user device 100, the microphone, and/or the speaker which may include characterizing at least one of a user identifier, a user device identifier, user facial expression, user heart rate, a user device type, the user's hearing ability, a microphone transfer function indication, and a speaker transfer function indication. The user's facial expression may be determined based on processing video from a camera through a facial expression analysis program, such as the Rekognition facial recognition software product developed by Amazon. The user's heart rate may be sensed by a smartwatch which is wirelessly connected to the user device 100.

The analysis circuit 120 may also characterize current user actions to control music playout which are correlated in time to the characterized ambient noise features and the characterized music features. The characterization of the user actions to control music playout can include characterizing user control of at least one of volume of the music during playout, equalization of the music during playout, pausing or stopping music playout, initiate change of music playout from one music track to another music track, select location within a music track presently being played where a change of music playout is to occur to another music track, and modify which music tracks are contained in an ordered playlist that will be played in the future through the user device 100. The analysis circuit 120 or another circuit, e.g., the training circuit 242, may also correlate what user actions are taken to control music playout to a combination of the characterized ambient noise features and the characterized music features.

For example, the analysis circuit 120 or another circuit, e.g., the training circuit 242, may correlate occurrence of certain characterized ambient noise features and occurrence of a certain observable user reaction, e.g., user facial expression (indicating concern), pulse rate change, etc., with a user's resulting action to change music track, pause music playout, increase music loudness, etc. The adaptive music system may be able to learn over time how to select music tracks which the user is likely to prefer to listen to when subjected to certain ambient noise features. The adaptive music system may form a plurality of playlists of organized songs which can be switched between responsive to changes in the ambient noise features.

The machine learning processing circuit 130 is configured to generate a music playout command responsive to processing at least the characterized ambient noise features and the characterized music features through the machine learning model 132 that has been trained based on a combination of historical user actions to control music playout, historically characterized ambient noise features that are correlated in time to the historical user actions, and historically characterized music features that are correlated in time to the historical user actions.

The machine learning processing circuit 130 may operate in a run-time mode and a training mode, although those modes are not mutually exclusive and at least some training may be performed during run-time.

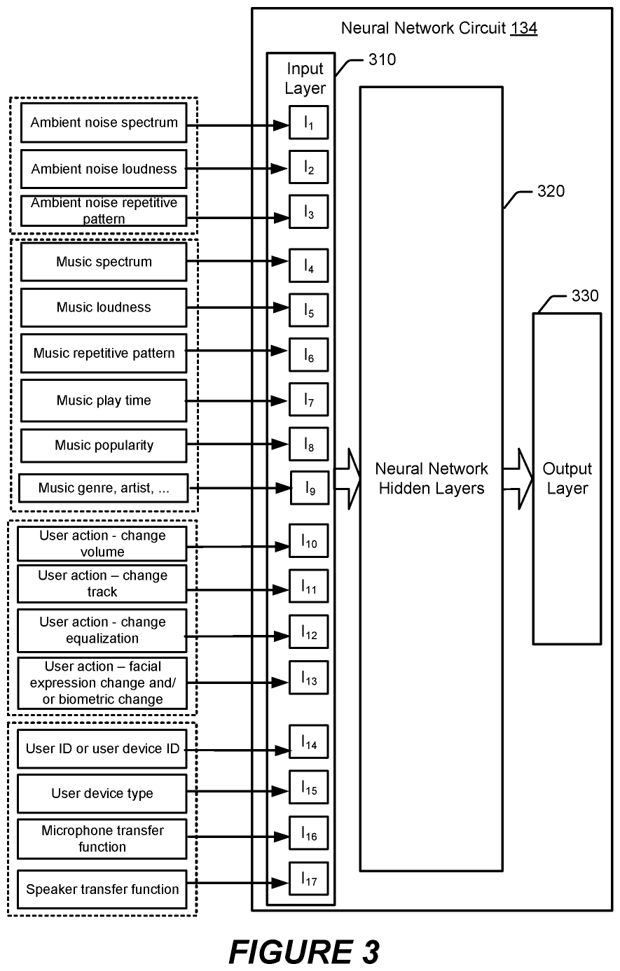

During run-time, the characterization data output by the analysis circuit 120 may be conditioned by a data preconditioning circuit 220 to, for example, normalize values of the characterization data and/or filter the characterization data before being passed through run-time path 240 to the machine learning processing circuit 130. The machine learning processing circuit 130 includes the machine learning model 132 which, in some embodiments, includes a neural network circuit 134 which will be described in further detail with regard to FIG. 3. The characterization data is processed through the machine learning model 132 to generate a music playout command.

The music playout control circuit 140 is configured to control music playout through the user device 100 responsive to the music playout command In some embodiments, the music playout control circuit 140 is configured to control at least one of volume of the music during playout, equalization of the music during playout, pausing or stopping music playout, initiate change of music playout from one music track to another music track, select location within a music track presently being played where a change of music playout is to occur to another music track, and modify which music tracks are contained in an ordered playlist that will be played in the future through the user device 100. The music playout control circuit 140 may communicate a command to the music streaming server 200 and/or to the user device 100 to control music playout. As explained above, the music playout control circuit 140 may be part of the music streaming server 200 and/or the user device 100. Thus, the command may be communicated in a message passed through the network 210 or may be a value passed between applications, e.g., through application programming interfaces, which are executed by a same processor or multiprocessor computer.

For example, a specific music track can include different instruments, vocals, etc. in different parts of a song; e.g. a song may include a first half that is intensive and strong (i.e. “fortissimo” or “forte fortissimo”) drums solo, followed by a last half in which a vocalist is paired with a violin both softly (e.g. “piano” or “pianissimo”). In such scenario, a user when subjected to a certain strength and certain characteristics of current ambient noise, may choose to swap from this specific music track just after the soft part is being entered. In this aspect, the machine learning model 132 can learn that the last half of the music track is to be swapped with another music track when the ambient noise reaches certain characteristics. The machine learning model 132 may also learn that the user prefers to swap away from music segments carrying certain instruments (sound features) faster (i.e. shorted time between music song sound feature transition to that a user action is triggered) than other segment carrying other instruments. The machine learning model 132 may also learn that parts of music songs carrying similar sound characteristics may be managed in similar ways given a specific user and given certain ambient noise features.

When the machine learning model 132 includes a neural network circuit 134, it may be configured as shown in FIG. 3. The neural network circuit 134 may include a neural network model that is implemented in software executed from at least one memory by at least one processor, and/or may be implemented in a non-instruction processing based finite state machine circuit, analog circuit, and/or hybrid analog-digital circuit.

Referring to FIG. 3, the neural network circuit 134 can include an input layer 310 with input nodes “I”, a sequence of hidden layers 320 each having a plurality of combining nodes, and an output layer 330 having at least one output node.

The machine learning processing circuit 130 can be configured to provide different ones of the characterized ambient noise features and the characterized music features to different ones of the input nodes “I” of the neural network circuit 134, such as shown in FIG. 3, and configured to generate the music playout command based on output of the at least one output node of the neural network circuit 134.

In the non-limiting illustrative embodiment of FIG. 3, the various different illustrated types of characterization data values are separately provided to different corresponding ones of the input nodes I₁ through I₁₇. The characterization data values are generated by the analysis circuit 120 and may be conditioned by the data preconditioning circuit 220 such as explained above. The characterization data values can characterize environmental ambient noise, the music, the user and/or the user device, the microphone, and/or the speaker. In FIG. 3, the characterization data values characterize the ambient noise spectrum, ambient noise loudness, ambient noise repetitive pattern, music spectrum, musical loudness, music repetitive pattern, music playtime, music popularity, music genre, music artist, user action to change volume, user action to change music track, user action to change equalization, facial expression change and/or biometric change, user identifier and/or user device identifier, user device type, microphone transfer function, and speaker transfer function, which are respectively provided to different ones of the input nodes I₁ through I₁₇.

During run-time mode and training mode, the interconnected structure of the neural network between the input nodes of the input layer 310, the combining nodes of the hidden layers 320, and the output node(s) of the output layer 330 can cause the inputted characterization values to simultaneously be processed to influence the generated music playout command.

Each of the input nodes in the input layer 310 multiply the input characterization data value by a weight that is assigned to the input node to generate a weighted node value. When the weighted node value exceeds a firing threshold assigned to the input node, the input node then provides the weighted node value to the combining nodes of a first one of the sequence of the hidden layers 320. The input node does not output the weighted node value unless if the condition is satisfied where the weighted node value exceeds the assigned firing threshold.

Furthermore, the neural network circuit 134 operates the combining nodes of the first one of the sequence of the hidden layers 320 using weights that are assigned thereto to multiply and mathematically combine weighted node values provided by the input nodes to generate combined node values, and when the combined node value generated by one of the combining nodes exceeds a firing threshold assigned to the combining node to then provide the combined node value to the combining nodes of a next one of the sequence of the hidden layers 320.

Furthermore, the neural network circuit 134 operates the combining nodes of a last one of the sequence of hidden layers 320 using weights that are assigned thereto to multiply and combine the combined node values provided by a plurality of combining nodes of a previous one of the sequence of hidden layers to generate combined node values, and when the combined node value generated by one of the combining nodes exceeds a firing threshold assigned to the combining node to then provide the combined node value to the at least one output node of the output layer 330.

Finally, the at least on output node of the output layer 330 is then operated to combine the combined node values from the last one of the sequences of hidden layers 320 to generate the output value used for generating the music playout command.

Referring again to FIG. 2, the training circuit 242 is configured to train the machine learning model 132 based on a combination of historical user actions to control music playout, historically characterized ambient noise features that are correlated in time to the historical user actions, and historically characterized music features that are correlated in time to the historical user actions.

When the machine learning model 132 includes the neural network circuit 134, such as the circuit shown in FIG. 3, the analysis circuit 120 can be configured to characterize a current user action to control music playout correlated in time to the characterized ambient noise features and the characterized music features. The training circuit 242 can be configured according to the operations 500 shown in FIG. 5 to train the machine learning model 132 based on the characterized ambient noise features, the characterized music features, and the characterized current user action while the digitized music is being played through user device 100 to the speaker.

Off-line training of the neural network circuit 134 can include the training circuit 242 adapting 502 the weights and/or adapting 504 the firing thresholds that are used by at least the input nodes of the neural network circuit 134 based on a combination of historical user actions to control music playout, historically characterized ambient noise features that are correlated in time to the historical user actions, and historically characterized music features that are correlated in time to the historical user actions. The training circuit 242 may similarly adapt 502 the weights and/or adapt 504 the firing thresholds that are used by the combining nodes of one or more of the hidden layers 320 and/or the output nodes of the output layer 330. The historical characterization data values may be obtained from a historical data repository 230. The historical data repository 230 may be populated over time with characterization data values that are output by the analysis circuit 120.

Data volatility in the magnitude and/or sign of the characterization data values which are input to the neural network circuit 134 may cause instability in the training operation of the neural network circuit 134. For example, having a high rate of change over time in values of one type of characterization data may cause the neural network circuit 134 to become overly sensitive during training to spurious data that has a low causal relationship to what a user would desire for how music playout is controlled in the presence of environment ambient noise while listening to music having certain characteristics. In one embodiment, the analysis circuit is further configured to characterize data volatility based on rate of change over time of at least one of the historical user actions, the historically characterized ambient noise features that are correlated in time to the historical user actions, and the historically characterized music features that are correlated in time to the historical user actions. The training circuit 242 is then further configured to adapt the weights and/or firing thresholds that are used by at least the input nodes of the neural network circuit 134 based on the characterized data volatility. Thus, for example, the training circuit 242 may respond to an increased data volatility characterization by decreasing an amount of change and/or a rate of change it makes over repetitive training cycles to the weights and/or firing thresholds of the input node, the combining nodes, and/or the output nodes. Conversely, the training circuit 242 may respond to a decrease data volatility characterization by increasing an amount of change and/or a rate of change it makes over repetitive training cycles to the weights and/or firing thresholds of the input node, the combining nodes, and/or the output nodes.

The training circuit 242 may also adapt 502 the weights and/or adapt 504 the firing thresholds of the input node, the combining nodes, and/or the output nodes in more real-time based on the characterization data values that are output by the analysis circuit 120 while music is being played to the user device 100. In one embodiment, the analysis circuit 120 is further configured to characterize a user action to control music playout correlated in time to the characterized ambient noise features and the characterized music features. The training circuit 242 is further configured to adapt 502 the weights and/or adapt 504 the firing thresholds that are used by at least the input nodes of the neural network circuit 134 based on the characterized ambient noise features, the characterized music features, and the characterized user action while the digitized music is being played through user device 100 to the speaker.

As explained above, the current user action and/or historical user actions to control music playout can be characterized to include information indicating at least one of a user changing volume of the music during playout, a user changing equalization of the music during playout, a user pausing or stopping music playout, a user initiating change of music playout from one music track to another music track, a user modifying which music tracks contained in an ordered playlist are played in the future through the user device 100. The training circuit 242 may be configured to train the machine learning model 132 based on information indicating at least one of a user identifier, a user device identifier, a user device type, a user's hearing ability, a microphone transfer function indication, and a speaker transfer function indication.

In some further embodiments, the adaptive music system 110 is configured to adapt how it controls music playback based on what environment ambient noise is predicted to occur along an estimated travel path of the user device 100, such as when the user device 100 is following a planned route (e.g., Google Maps route) through a geographic region (e.g., roadways) having known ambient noise characteristics (e.g., obtained from a network server storing a geographic region noise map). The known ambient noise characteristics may be obtained from a system providing vehicles with information about road condition, ongoing constructions, traffic disturbance information, etc. As an example, it may be determined that the user will be disturbed by noise from a construction site in a short time, e.g., 37 seconds, and music may be selected accordingly. That is, music is selected not only based on a current ambient noise, but on expected ambient noise during the duration of the music track.

A shuffling feature may consider future “hear-ability/usability” of e.g. music or playlists in its selection (random selection process) of ordered lists of music tracks. In an ordinary shuffle functionality, the probability of selecting one specific music track among N available music tracks is typically 1/N; with future-expected-ambient-noise-features added to the selection model, said music song selection probability may be increased/decreased in respect to whatever future ambient noise features that are identified and/or predicted to be present at the upcoming time for play-out of said music track

In one embodiment, the analysis circuit 120 is further configured to characterize predicted ambient noise features of digitized ambient noise that is predicted to be obtained from the microphone circuit at a location along an estimated route of the user device 100 and to characterize predicted music features of digitized music of a music track that is predicted to be playing when the user device 100 reaches the location. The machine learning processing circuit 130 is correspondingly configured to generate the music playout command responsive to processing the characterized predicted ambient noise features and the characterize predicted music features through the machine learning model 132.

As explained above, the analysis circuit may characterize the user's facial expressions which can then be fed into the machine learning processing circuit. The user device 100 may have access to capabilities for user facial emotion classification, either residing in software run on the user device 100 or in a network server that through communication with the user device 100 may receive a facial image, a parameterization or similar thereof, and based on that may provide a characterization of the user's facial expression. In this aspect, the machine learning model 132 may be trained based on the characterization of the user's facial expression and how it changes over time based on correlation to the characterized ambient noise features and the characterized music features of digitized music being played through the user device 100. For example, a user may become disturbed, unsatisfied or dis-enjoyed with music track's audibility, at some point where the music heard becomes overtaken by the ambient noise. The corresponding change in user facial expression can be by the machine learning model 132, so that the music playout control is adapted in the future.

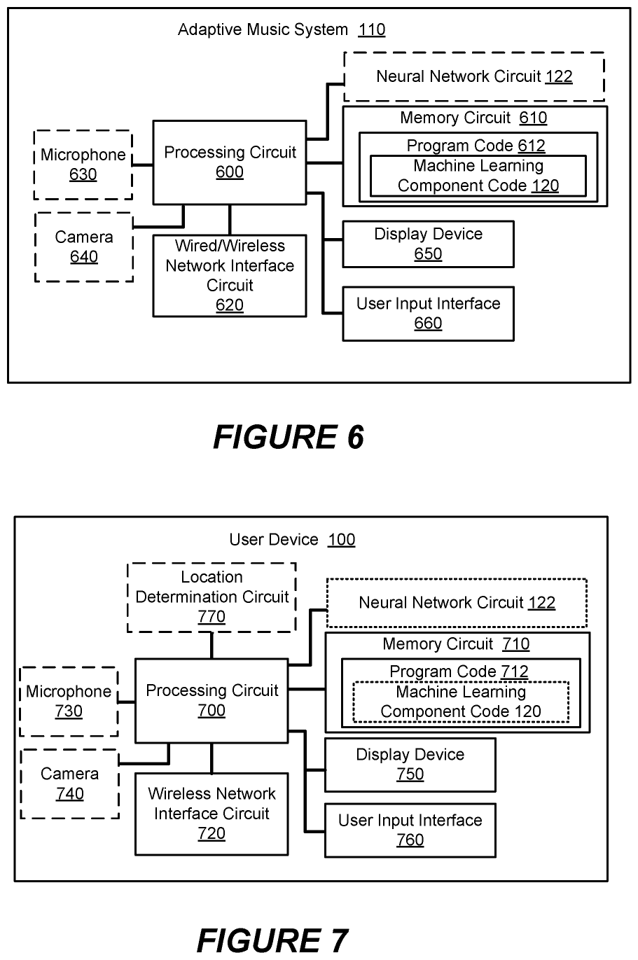

FIG. 6 is a block diagram of component circuits of an adaptive music system 110 which are configured to operate in accordance with some embodiments of the present disclosure. Referring to FIG. 6, the adaptive music system 110 includes a wired/wireless network interface circuit 620, at least one processing circuit 600, and at least one memory circuit 610 (memory) which is also described below as a computer readable medium. The processing circuit 600 may correspond to the processing circuit 112 in FIG. 1. The memory 610 stores program code 612 that is executed by the processing circuit 600 to perform operations disclosure herein for at least one embodiment of an adaptive music system. The program code 612 may include machine learning component code 120 which is configured to perform at least some of the operations recited herein for machine learning. The processing circuit 600 may include one or more data processing circuits, such as a general purpose and/or special purpose processor (e.g., microprocessor and/or digital signal processor), which may be collocated or distributed across one or more data networks. The adaptive music system 110 may further include a display device 650, either input interface 660, a microphone 630, and/or a camera 640. As explained above, the adaptive music system 110 may be at least partially implemented within a user device 100 and/or within a network server, such as a music streaming server.

FIG. 7 is a block diagram of circuits of a user device 100 that are configured in accordance with some other embodiments of the present disclosure. The user device 100 can include a wireless network interface circuit 720, at least one processing circuit 700, and at least one memory circuit 710 (memory) which is also described below as a computer readable medium. The processing circuit 700 may correspond to the processing circuit 112 in FIG. 1. The memory 710 stores program code 712 that is executed by the processing circuit 700 to perform operations disclosure herein for at least one embodiment of the user device. The program code 712 may include machine learning component code 120 which is configured to perform at least some of the operations recited herein for machine learning. The processing circuit 700 may include one or more data processing circuits, such as a general purpose and/or special purpose processor (e.g., microprocessor and/or digital signal processor), which may be collocated or distributed across one or more data networks. The user device 100 may further include a location determination circuit 770, a microphone 730, a display device 750, and a user input interface 760 (e.g., keyboard or touch sensitive display). The location determination circuit 770 can operate to determine the geographic location of the user device 100 based on satellite positioning (e.g., GNSS (Global Navigation Satellite Systems), GPS (Global Positioning System), GLONASS, Beidou or Galileo) and/or based on ground-based network-assisted positioning (e.g., cellular tower triangulation based on signaling time-of-flight or Wi-Fi based positioning).

Further definitions and embodiments are explained below.

In the above description of various embodiments of present inventive concepts, it is to be understood that the terminology used herein is for the purpose of describing particular embodiments only and is not intended to be limiting of present inventive concepts. Unless otherwise defined, all terms (including technical and scientific terms) used herein have the same meaning as commonly understood by one of ordinary skill in the art to which present inventive concepts belongs. It will be further understood that terms, such as those defined in commonly used dictionaries, should be interpreted as having a meaning that is consistent with their meaning in the context of this specification and the relevant art and will not be interpreted in an idealized or overly formal sense expressly so defined herein.

When an element is referred to as being “connected”, “coupled”, “responsive”, or variants thereof to another element, it can be directly connected, coupled, or responsive to the other element or intervening elements may be present. In contrast, when an element is referred to as being “directly connected”, “directly coupled”, “directly responsive”, or variants thereof to another element, there are no intervening elements present. Like numbers refer to like elements throughout. Furthermore, “coupled”, “connected”, “responsive”, or variants thereof as used herein may include wirelessly coupled, connected, or responsive. As used herein, the singular forms “a”, “an” and “the” are intended to include the plural forms as well, unless the context clearly indicates otherwise. Well-known functions or constructions may not be described in detail for brevity and/or clarity. The term “and/or” includes any and all combinations of one or more of the associated listed items.

It will be understood that although the terms first, second, third, etc. may be used herein to describe various elements/operations, these elements/operations should not be limited by these terms. These terms are only used to distinguish one element/operation from another element/operation. Thus, a first element/operation in some embodiments could be termed a second element/operation in other embodiments without departing from the teachings of present inventive concepts. The same reference numerals or the same reference designators denote the same or similar elements throughout the specification.

As used herein, the terms “comprise”, “comprising”, “comprises”, “include”, “including”, “includes”, “have”, “has”, “having”, or variants thereof are open-ended, and include one or more stated features, integers, elements, steps, circuits or functions but does not preclude the presence or addition of one or more other features, integers, elements, steps, circuits, functions or groups thereof. Furthermore, as used herein, the common abbreviation “e.g.”, which derives from the Latin phrase “exempli gratia,” may be used to introduce or specify a general example or examples of a previously mentioned item, and is not intended to be limiting of such item. The common abbreviation “i.e.”, which derives from the Latin phrase “id est,” may be used to specify a particular item from a more general recitation.

Example embodiments are described herein with reference to block diagrams and/or flowchart illustrations of computer-implemented methods, apparatus (systems and/or devices) and/or computer program products. It is understood that a block of the block diagrams and/or flowchart illustrations, and combinations of blocks in the block diagrams and/or flowchart illustrations, can be implemented by computer program instructions that are performed by one or more computer circuits, implemented by analog circuits, and/or implement by hybrid digital and analog circuits. Computer program instructions may be provided to a processing circuit of a general purpose computer circuit, special purpose computer circuit, and/or other programmable data processing circuit to produce a machine, such that the instructions, which execute via the processing circuit of the computer and/or other programmable data processing apparatus, transform and control transistors, values stored in memory locations, and other hardware components within such circuitry to implement the functions/acts specified in the block diagrams and/or flowchart block or blocks, and thereby create means (functionality) and/or structure for implementing the functions/acts specified in the block diagrams and/or flowchart block(s).

These computer program instructions may also be stored in a tangible computer-readable medium that can direct a computer or other programmable data processing apparatus to function in a particular manner, such that the instructions stored in the computer-readable medium produce an article of manufacture including instructions which implement the functions/acts specified in the block diagrams and/or flowchart block or blocks. Accordingly, embodiments of present inventive concepts may be embodied in hardware and/or in software (including firmware, resident software, micro-code, etc.) that runs on a processing circuit such as a digital signal processor, which may collectively be referred to as “circuitry,” “a module” or variants thereof.

It should also be noted that in some alternate implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of inventive concepts. Moreover, although some of the diagrams include arrows on communication paths to show a primary direction of communication, it is to be understood that communication may occur in the opposite direction to the depicted arrows.

Many variations and modifications can be made to the embodiments without substantially departing from the principles of the present inventive concepts. All such variations and modifications are intended to be included herein within the scope of present inventive concepts. Accordingly, the above disclosed subject matter is to be considered illustrative, and not restrictive, and the appended examples of embodiments are intended to cover all such modifications, enhancements, and other embodiments, which fall within the spirit and scope of present inventive concepts. Thus, to the maximum extent allowed by law, the scope of present inventive concepts are to be determined by the broadest permissible interpretation of the present disclosure including the following examples of embodiments and their equivalents, and shall not be restricted or limited by the foregoing detailed description.

1. An adaptive music system comprising at least one processing circuit operative to
characterize ambient noise features of digitized ambient noise obtained from a microphone circuit associated with a user device and to characterize music features of digitized music being played through the user device to a speaker;
generate a music playout command responsive to processing the characterized ambient noise features and the characterized music features through a machine learning model that has been trained based on a combination of historical user actions to control music playout, historically characterized ambient noise features that are correlated in time to the historical user actions, and historically characterized music features that are correlated in time to the historical user actions; and
control music playout through the user device responsive to the music playout command.

2. The adaptive music system of claim 1, wherein the at least one processing circuit is further operative to:
train the machine learning model based on a combination of historical user actions to control music playout, historically characterized ambient noise features that are correlated in time to the historical user actions, and historically characterized music features that are correlated in time to the historical user actions.

3. The adaptive music system of claim 2, wherein the at least one processing circuit is further operative to:
characterize a current user action to control music playout correlated in time to the characterized ambient noise features and the characterized music features; and
train the machine learning model based on the characterized ambient noise features, the characterized music features, and the characterized current user action while the digitized music is being played through user device to the speaker.

4. The adaptive music system of claim 1, wherein the at least one processing circuit comprises:
a neural network circuit including an input layer having input nodes, a sequence of hidden layers each having a plurality of combining nodes, and an output layer having an output node; and
the at least one processing circuit is further operative to provide different ones of the characterized ambient noise features and the characterized music features to different ones of the input nodes of the neural network circuit, and to generate the music playout command based on output of the output node of the neural network circuit.

5. The adaptive music system of claim 4, wherein the at least one processing circuit is further operative to:
adapt weights and/or firing thresholds that are used by at least the input nodes of the neural network circuit based on a combination of historical user actions to control music playout, historically characterized ambient noise features that are correlated in time to the historical user actions, and historically characterized music features that are correlated in time to the historical user actions.

6. The adaptive music system of claim 5, wherein the at least one processing circuit is further operative to:
characterize data volatility based on rate of change over time of at least one of the historical user actions, the historically characterized ambient noise features that are correlated in time to the historical user actions, and the historically characterized music features that are correlated in time to the historical user actions; and
adapt the weights and/or firing thresholds that are used by at least the input nodes of the neural network circuit based on the characterized data volatility.

7. The adaptive music system of claim 5, wherein the at least one processing circuit is further operative to:
characterize user action to control music playout correlated in time to the characterized ambient noise features and the characterized music features; and
adapt weights and/or firing thresholds that are used by at least the input nodes of the neural network circuit based on the characterized ambient noise features, the characterized music features, and the characterized user action while the digitized music is being played through user device to the speaker.

8. The adaptive music system of claim 1, wherein the at least one processing circuit is further operative to characterize ambient noise features of digitized ambient noise obtained from the microphone circuit associated with the user device, by:
characterizing in the digitized ambient noise at least one of ambient noise frequency spectrum, ambient noise acoustic fingerprint, ambient noise loudness, and ambient noise repetitive pattern.

9. The adaptive music system of claim 1, wherein the at least one processing circuit is further operative to characterize music features of digitized music being played through user device to the speaker, by:
characterizing in the digitized music being played through user device at least one of music frequency spectrum, music acoustic fingerprint, music loudness, music repetitive pattern, music play time, music popularity, music genre, and music artist.

10. The adaptive music system of claim 1, wherein the at least one processing circuit is further operative to control music playout through the user device responsive to the music playout command, by:
controlling at least one of volume of the music during playout, equalization of the music during playout, pausing or stopping music playout, initiate change of music playout from one music track to another music track, select location within a music track presently being played where a change of music playout is to occur to another music track, and modify which music tracks are contained in an ordered playlist that will be played in the future through the user device.

11. The adaptive music system of claim 1, wherein the at least one processing circuit is further operative to generate the music playout command responsive to processing through the machine learning model information indicating at least one of a user identifier, a user device identifier, user facial expression, user heart rate, a user device type, user's hearing ability, a microphone transfer function indication, and a speaker transfer function indication.

12. The adaptive music system of claim 1, wherein the historical user actions to control music playout are characterized to include information indicating at least one of a user changing volume of the music during playout, a user changing equalization of the music during playout, a user pausing or stopping music playout, a user initiating change of music playout from one music track to another music track, a user modifying which music tracks contained in an ordered playlist are played in the future through the user device.

13. The adaptive music system of claim 12, wherein the at least one processing circuit is further operative to train the machine learning model based on information indicating at least one of a user identifier, a user device identifier, a user device type, a user's hearing ability, a microphone transfer function indication, and a speaker transfer function indication.

14. The adaptive music system of claim 1, wherein the at least one processing circuit is further operative to:
characterize predicted ambient noise features of digitized ambient noise that is predicted to be obtained from the microphone circuit at a location along an estimated route of the user device and to characterize predicted music features of digitized music of a music track that is predicted to be playing when the user device reaches the location; and
generate the music playout command responsive to processing the characterized predicted ambient noise features and the characterize predicted music features through the machine learning model.

15. The adaptive music system of claim 1, wherein the at least one processing circuit is contained in the user device which is configured as a mobile audio device or a stationary audio device.

16. The adaptive music system of claim 1, wherein the at least one processing circuit is contained in a network server that is communicatively connected to the user device.

17. A method by an adaptive music system comprising:
characterizing ambient noise features of digitized ambient noise obtained from a microphone circuit associated with a user device and characterizing music features of digitized music being played through user device to a speaker;
generating a music playout command responsive to processing the characterized ambient noise features and the characterized music features through a machine learning model that has been trained based on a combination of historical user actions to control music playout, historically characterized ambient noise features that are correlated in time to the historical user actions, and historically characterized music features that are correlated in time to the historical user actions; and
controlling music playout through the user device responsive to the music playout command.

18. The method of claim 17, further comprising:
training the machine learning model based on a combination of historical user actions to control music playout, historically characterized ambient noise features that are correlated in time to the historical user actions, and historically characterized music features that are correlated in time to the historical user actions.

19. The method of claim 18, wherein:
the characterizing comprises characterizing a current user action to control music playout correlated in time to the characterized ambient noise features and the characterized music features; and
the training comprises training the machine learning model based on the characterized ambient noise features, the characterized music features, and the characterized current user action while the digitized music is being played through user device to the speaker.

20. The method of claim 17, wherein:
the machine learning model comprises a neural network circuit including an input layer having input nodes, a sequence of hidden layers each having a plurality of combining nodes, and an output layer having an output node;
the generating comprises providing different ones of the characterized ambient noise features and the characterized music features to different ones of the input nodes of the neural network circuit, and generating the music playout command based on output of the output node of the neural network circuit.

21. The method of claim 20, further comprising:
adapting weights and/or adapting firing thresholds that are used by at least the input nodes of the neural network circuit based on a combination of historical user actions to control music playout, historically characterized ambient noise features that are correlated in time to the historical user actions, and historically characterized music features that are correlated in time to the historical user actions.

22. The method of claim 21, wherein:
the characterizing comprises characterizing data volatility based on rate of change over time of at least one of the historical user actions, the historically characterized ambient noise features that are correlated in time to the historical user actions, and the historically characterized music features that are correlated in time to the historical user actions; and
the adapting weights and/or the adapting firing thresholds comprises adapting the weights and/or firing thresholds that are used by at least the input nodes of the neural network circuit based on the characterized data volatility.

23. The method of claim 21, wherein:
the characterizing comprises characterizing user action to control music playout correlated in time to the characterized ambient noise features and the characterized music features; and
adapting weights and/or adapting firing thresholds that are used by at least the input nodes of the neural network circuit comprises adapting the weights and/or firing thresholds that are used by at least the input nodes of the neural network circuit based on the characterized ambient noise features, the characterized music features, and the characterized user action while the digitized music is being played through user device to the speaker.

24. The method of claim 17, wherein the characterizing ambient noise features of digitized ambient noise obtained from a microphone circuit associated with a user device, comprises:
characterizing in the digitized ambient noise at least one of ambient noise frequency spectrum, ambient noise loudness, and ambient noise repetitive pattern.

25. The method of claim 17, wherein the characterizing music features of digitized music being played through user device to the speaker, comprises:
characterizing in the digitized music being played through user device at least one of music frequency spectrum, music loudness, music repetitive pattern, music play time, music popularity, music genre, and music artist.

26. The method of claim 17, wherein the controlling music playout through the user device, comprises:
controlling at least one of volume of the music during playout, equalization of the music during playout, initiate change of music playout from one music track to another music track, select location within a music track presently being played where a change of music playout is to occur to another music track, and modify which music tracks are contained in an ordered playlist that will be played in the future through the user device.

27. The method of claim 17, wherein the generating a music playout command responsive to processing the characterized ambient noise features and the characterized music features through the machine learning model, comprises generate the music playout command responsive to processing through the machine learning model information indicating at least one of a user identifier, a user device identifier, user facial expression, user heart rate, a user device type, user's hearing ability, a microphone transfer function indication, and a speaker transfer function indication.

28. The method of claim 17, wherein the historical user actions to control music playout are characterized to include information indicating at least one of a user changing volume of the music during playout, a user changing equalization of the music during playout, a user pausing or stopping music playout, a user initiating change of music playout from one music track to another music track, a user modifying which music tracks contained in an ordered playlist are played in the future through the user device.

29. The method of claim 28, wherein the training of the machine learning model is further based on information indicating at least one of a user identifier, a user device identifier, a user device type, a user's hearing ability, a microphone transfer function indication, and a speaker transfer function indication.

30. The method of claim 17, wherein:
the characterizing comprises characterizing predicted ambient noise features of digitized ambient noise that is predicted to be obtained from the microphone circuit at a location along an estimated route of the user device and characterizing predicted music features of digitized music of a music track that is predicted to be playing when the user device reaches the location; and
the generating a music playout command responsive to processing the characterized ambient noise features and the characterized music features through the machine learning model, comprises generating the music playout command responsive to processing the characterized predicted ambient noise features and the characterize predicted music features through the machine learning model.

31. (canceled)

32. (canceled)

33. (canceled)
